(19) United States
(12) Patent Application Publication
(10) Pub. No.: US 2025/0085464 A1
(43) Pub. Date: Mar. 13, 2025

(54) LIGHT EMITTING DISPLAY DEVICE

(71) Applicant: Samsung Display Co., LTD., Yongin-si Gyeonggi-do (KR)

(72) Inventors: Beong-Hun BEON, Yongin-si (KR); Duk Jin LEE, Yongin-si (KR); Woo Suk JUNG, Yongin-si (KR)

(21) Appl. No.: 18/651,740

(22) Filed: May 1, 2024

(30) Foreign Application Priority Data
Sep. 11, 2023 (KR) 10-2023-0120624

(51) Int. Cl. G02B 5/30; G02B 1/11; H01L 25/075

(52) U.S. Cl. CPC G02B 5/3016; G02B 1/11; H01L 25/0753

(57) ABSTRACT

A light emitting display device includes a display panel including a light emitting diode, a positive C plate disposed in front of the display panel, a positive A plate disposed in front of the positive C plate, a negative A plate disposed in front of the positive A plate, and a polarizer disposed in front of the negative A plate, wherein the polarizer includes, a polarizing layer having an absorption axis, and a negative C plate disposed between the polarizing layer and the negative A plate, wherein the positive C plate, the positive A plate, the negative A plate, and the negative C plate each have positive wavelength dispersion characteristics, and wherein the light emitting display device has negative wavelength dispersion characteristics at the front as a whole.

This application claims priority to Korean Patent Application No. 10-2023-0120624, filed on Sep. 11, 2023, and all the benefits accruing therefrom under 35 U.S.C. § 119, the content of which in its entirety is herein incorporated by reference.

### BACKGROUND

### 1. Field

The present invention relates to a light emitting display device, and more particularly, to a light emitting display device including a polarizer and a compensation film on the front surface.

### 2. Description of the Related Art

A light emitting display device is a self-luminous display device that displays images by emitting light from a light emitting diode.

Meanwhile, a liquid crystal display device displays an image by adjusting the degree to which it blocks light provided by a light unit, and in order to block light, two polarizers are formed at the top and bottom as well as the liquid crystal layer.

Therefore, in general, a light emitting display device, unlike a liquid crystal display device, can display an image without including a polarizer.

### SUMMARY

Embodiments provide a light emitting display device that prevents external light from being reflected.

Embodiments provide a light emitting display device with improved omnidirectional reflection characteristics or reflection color characteristics by having negative wavelength dispersion.

Embodiments provide a light emitting display device formed to have negative wavelength dispersion by merging layers that individually have positive dispersion.

In an embodiment, a light emitting display device includes a display panel including a light emitting diode, a positive C plate disposed in front of the display panel, a positive A plate disposed in front of the positive C plate, a negative A plate disposed in front of the positive A plate, and a polarizer disposed in front of the negative A plate, wherein the polarizer includes a polarizing layer having an absorption axis, and a negative C plate disposed between the polarizing layer and the negative A plate, wherein the positive C plate, the positive A plate, the negative A plate, and the negative C plate each have positive wavelength dispersion characteristics, wherein the light emitting display device includes negative wavelength dispersion characteristics at the front as a whole.

In an embodiment, the light emitting display device has front reflectance of external light of 10%.

In an embodiment, the positive C plate, the positive A plate, and the negative A plate are formed by arranging liquid crystal molecules, wherein the negative C plate may be attached to one side of the polarizing layer in the form of a film.

In an embodiment, the positive C plate may have a thickness direction retardation value in a range of about −50 nm or more and about −85 nm or less.

In an embodiment, the positive A plate may have an in-plane retardation value in a range of about 160 nm or more and about 180 nm or less.

In an embodiment, the liquid crystal molecules included in the positive A plate have a twisted liquid crystal arrangement, wherein the twisted liquid crystal molecules in the positive A plate have an orientation angle of about 50 degrees with respect to the first direction and a tilt angle in the first direction of about −31 degrees.

In an embodiment, the negative A plate may have an in-plane retardation value in the range of about −160 nm or more and about −180 nm or less.

In an embodiment, the negative A plate may have an angle of about −31 degrees with respect to the delay axis and the first direction.

In an embodiment, the negative C plate may have a thickness direction

retardation value in the range of about 10 nm or more and about 50 nm or less.

In an embodiment, the absorption axis of the polarizing layer may have an angle of about 45 degrees with respect to the first direction.

In an embodiment, the light emitting display device may further include an adhesive layer disposed between the positive A plate and the negative A plate, and between the negative A plate and the polarizer.

In an embodiment, a light emitting display device includes a display panel including a light emitting diode, a positive C plate disposed in front of the display panel, a positive A plate disposed in front of the positive C plate, a negative A plate disposed in front of the positive A plate, and a polarizer disposed in front of the negative A plate, wherein the polarizer includes a polarizing layer having an absorption axis, and a negative C plate disposed between the polarizing layer and the negative A plate, wherein the positive C plate has a thickness direction retardation value in the range of about −50 nm to about −85 nm, wherein the positive A plate has a front retardation value and the negative A plate has a front retardation value in the range of about −160 nm or more and about −180 nm or less, and the negative C plate has a thickness direction retardation value in the range of about 10 nm or more and about 50 nm or less.

In an embodiment, the positive C plate can be formed by aligning liquid crystal molecules.

In an embodiment, the positive A plate is formed by twisting liquid crystal molecules, wherein the twisted liquid crystal molecules of the positive A plate can have an angle of about 50 degrees in the first direction as an orientation angle, and can have an angle of about −31 degrees in the first direction as a tilt angle.

In an embodiment, the negative A plate is formed by arranging liquid crystal molecules, wherein the negative A plate may have a delay axis at an angle of about −31 degrees with respect to the first direction.

In an embodiment, the negative C plate may be attached in the form of a film to one side of the polarizing layer.

In an embodiment, the absorption axis of the polarizing layer may have an angle of about 45 degrees with respect to the first direction.

In an embodiment, the light emitting display device may further include an adhesive layer disposed between the positive A plate and the negative A plate.

In an embodiment, the light emitting display device may further include an adhesive layer disposed between the negative A plate and the polarizer.

In an embodiment, the positive C plate, the positive A plate, the negative A plate, and the negative C plate each have positive wavelength dispersion characteristics, and may be configured to have overall negative wavelength dispersion characteristics at the front.

According to embodiments, a negative C plate is formed at the inside of the polarizer, and a negative A plate and a positive A plate are disposed underneath the negative C plate, have negative wavelength dispersion properties, can reduce the reflectivity of external light, and can enhance omnidirectional reflection characteristics or reflection color characteristics.

According to embodiments, the light emitting display device may have negative wavelength dispersion although only layers that individually have positive wavelength dispersion are used.

### BRIEF DESCRIPTION OF THE DRAWINGS

The above and other advantages and features of the invention will become more apparent by describing in further detail embodiments thereof with reference to the accompanying drawings, in which:

FIG. 1 is a exploded schematic view of a light emitting display device, according to an embodiment.

FIG. 2 is a schematic cross-sectional view of the light emitting display device of FIG. 1, according to an embodiment.

FIG. 3 is a schematic cross-sectional view of an optical layer disposed on the front of a display panel in the light emitting display device of FIG. 1, according to an embodiment.

FIG. 4 is a diagram showing the specific structure of some of the optical layers of the display panel of FIG. 3, according to an embodiment.

FIG. 5 is a diagram showing the structure of a positive C plate, according to an embodiment.

FIG. 6 is a diagram showing the structure of a positive C plate, according to an embodiment.

FIG. 7 is a diagram showing the structure of a positive A plate, according to an embodiment.

FIG. 8 is a diagram showing the structure of a positive A plate, according to an embodiment.

FIG. 9 is a diagram showing the structure of a negative A plate, according to an embodiment.

FIG. 10 is a diagram showing the structure of a negative A plate, according to an embodiment.

FIG. 11 is a diagram showing the structure of a negative C plate, according to an embodiment.

FIG. 12 is a diagram showing the structure of a negative C plate, according to an embodiment.

FIG. 13 is a diagram illustrating the anisotropic characteristics separately, according to an embodiment.

FIG. 14 is a spherical coordinate diagram shown to help understand polarization characteristics of the light emitting display device of FIG. 3, according to an embodiment.

FIG. 15 is a spherical coordinate diagram shown to help understand polarization characteristics of the light emitting display device of FIG. 3, according to an embodiment.

FIG. 16 is a spherical coordinate diagram shown to help understand polarization characteristics of the light emitting display device of FIG. 3, according to an embodiment.

FIG. 17 is a spherical coordinate diagram shown to help understand polarization characteristics of the light emitting display device of FIG. 3, according to an embodiment.

FIG. 18 is a spherical coordinate diagram shown to help understand polarization characteristics of the light emitting display device of FIG. 3, according to an embodiment.

FIG. 19 is a spherical coordinate diagram shown to help understand polarization characteristics of the light emitting display device of FIG. 3, according to an embodiment.

FIG. 20 is a spherical coordinate diagram shown to help understand polarization characteristics of the light emitting display device of FIG. 3, according to an embodiment.

FIG. 21 is a spherical coordinate diagram shown to help understand polarization characteristics of the light emitting display device of FIG. 3, according to an embodiment.

FIG. 22 is a diagram showing the structure and reflection characteristics of comparative examples and some examples, according to an embodiment.

FIG. 23 is a diagram showing the structure and reflection characteristics of comparative examples and some examples, according to an embodiment.

FIG. 24 is a graph showing reflection characteristics depending on the angle of some plates included in the optical layer, according to an embodiment.

FIG. 25 is a graph showing reflection characteristics depending on the angle of some plates included in the optical layer, according to an embodiment.

FIG. 26 is a graph showing reflection characteristics depending on the angle of some plates included in the optical layer, according to an embodiment.

FIG. 27 is a graph showing reflection characteristics depending on the angle of some plates included in the optical layer, according to an embodiment.

FIG. 28 is a diagram showing the structure and reflection characteristics of comparative examples and some examples, according to an embodiment.

FIG. 29 is a diagram showing the structure and reflection characteristics of comparative examples and some examples, according to an embodiment.

FIG. 30 is a diagram showing reflection characteristics of comparative examples and various examples, according to an embodiment.

FIG. 31 is a diagram showing various optical properties of the film according to stretching, according to an embodiment.

FIG. 32 is a diagram illustrating various examples of photo-alignment, according to embodiments.

FIG. 33 is a diagram illustrating various examples of rod-structured liquid crystal molecules, according to an embodiment.

### DETAILED DESCRIPTION

Hereinafter, with reference to the attached drawings, various embodiments will be described in detail so that those skilled in the art can easily implement the present invention.

The invention may be implemented in many different forms and is not limited to the embodiments described herein.

In order to clearly explain the present invention, parts that are not relevant to the description are omitted, and identical or similar components are assigned the same reference numerals throughout the specification. Within the Figures and the text of the disclosure, a reference number indicating a singular form of an element may also be used to reference a plurality of the singular element.

In addition, the size and thickness of each component shown in the drawings are shown arbitrarily for convenience of explanation, so the present invention is not limited to that which is shown.

In the drawings, the thicknesses are enlarged to clearly express various layers and areas.

And in the drawings, for convenience of explanation, the thicknesses of some layers and regions are exaggerated.

Additionally, when a part such as a layer, membrane, region, plate, or component is said to be related to another element, such as being “above” or “on” another part, this means not only when the part is “directly above” another part, but also when there is another part in between. Conversely, when a part is said to be “right on top” of another part, it means that there is no other part in between.

In addition, being “above” or “on” a reference portion means being disposed above or below the reference portion and does not necessarily mean being disposed “above” or “on” in the direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target portion is viewed from above, and when reference is made to “in a cross-section,” this means when a cross-section of the target portion is cut vertically and viewed from the side.

In addition, throughout the specification, when “connected” is used, this does not mean only when two or more components are directly connected, but when two or more components are indirectly connected through other components, they are physically connected, this may include not only the case of being connected or electrically connected, but also the case of each part being substantially integrated, although referred to by different names depending on location or function, being connected to each other.

In addition, throughout the specification, when a portion such as wiring, a layer, a film, a region, a plate, or a component is said to “extend in the first or second direction,” this means not only a straight shape extending in that direction, but rather, it may be a structure that extends overall along the first or second direction, and also includes a structure that is bent at some part, has a zigzag structure, or extends while including a curved structure.

In addition, electronic devices include mobile phones, TVs, monitors, laptop computers, etc. containing display devices, display panels, etc. described in the specification, or display devices, display panels, etc. manufactured by the manufacturing method described in the specification, electronic devices included herein are also not excluded from the scope of rights of this specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise,” and variations such as “comprises” or “comprising,” will be understood to imply the inclusion of stated elements but not the exclusion of any other elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms)

used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

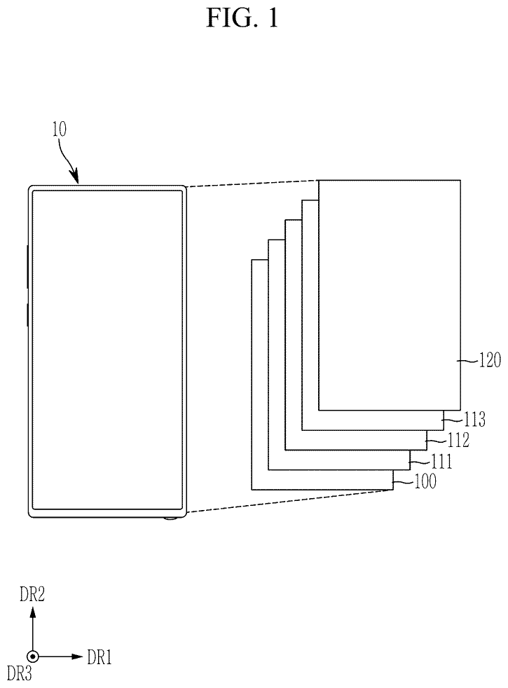

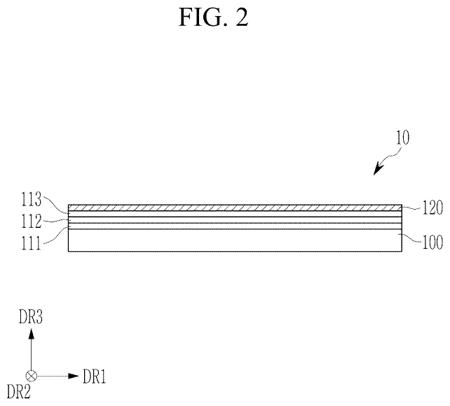

Hereinafter, the light emitting display device 10, according to an embodiment, will be briefly described through FIGS. 1 and 2

FIG. 1 is a schematic exploded view of a light-emitting display device, according to an embodiment, and FIG. 2 is a schematic cross-sectional view of the light emitting display device of FIG. 1, according to an embodiment.

In an embodiment, the light emitting display device 10 includes a display panel 100 and an optical layer disposed on the front surface in the third direction DR3.

In an embodiment, the optical layer includes a polarizer 120, a negative A plate 113, a positive A plate 112, and a positive C plate 111.

In an embodiment, the optical layers are arranged in the third direction DR3 on the display panel 100 in the following order: positive C plate 111, positive A plate 112, negative A plate 113, and polarizer 120.

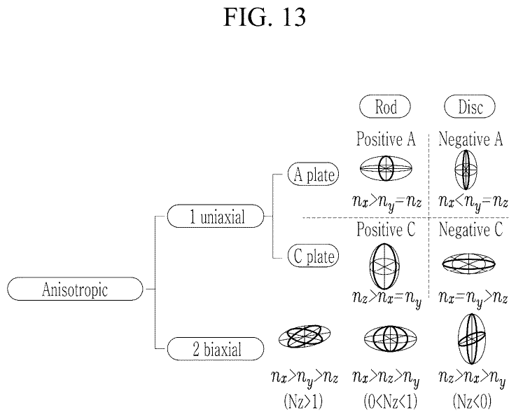

An embodiment of the positive, negative, and refractive index characteristics of the A plate and C plate are shown in FIG. 13.

In an embodiment, the display panel 100 includes a plurality of pixels, wherein one pixel includes a light emitting diode and a plurality of transistors that supply driving current to the light emitting diode to emit light.

In an embodiment, the plurality of transistors include a driving transistor that outputs a driving current to be transmitted to the light emitting diode and a plurality of switching transistors, and may additionally include a capacitor.

In an embodiment, the light emitting diode may be an organic light emitting diode or an inorganic light emitting diode.

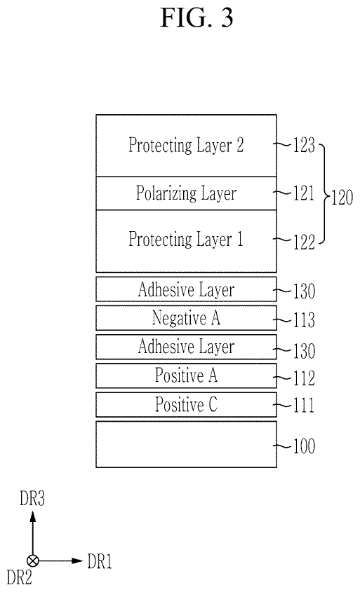

The structure of the optical layer disposed on the front of the display panel 100 will be examined in more detail through FIG. 3.

FIG. 3 is a schematic cross-sectional view of an optical layer disposed on the front of a display panel in the light emitting display device of FIG. 1, according to an embodiment.

In an embodiment, the light emitting display device 10 has a positive C plates 111 sequentially placed on the front side of the display panel 100 (upper side in the third direction DR3) from which light emitted from the light emitting diode disposed on the display panel 100 is emitted, and a positive A plate 112, a negative A plate 113, and a polarizer 120 are disposed.

In an embodiment and referring to FIG. 3, an adhesive layer 130 is disposed between the positive A plate 112 and the negative A plate 113, and between the negative A plate 113 and the polarizer 120 to attach them.

In an embodiment, the adhesive layer 130 may be disposed between the positive C plate 111 and the positive A plate 112 and/or between the positive C plate 111 and the display panel 100.

In an embodiment and referring to FIG. 3, the polarizer 120 is composed of multiple layers, and includes a negative C plate (122; also referred to as a back protection layer or first protection layer) and a front protection layer (123; also referred to as a second protection layer) that protect the polarizing layer 121 and provide a phase difference (retardation) to the light transmitted through it.

In an embodiment, among the optical layers included in the light emitting display device 10, the polarizing layer 121 included in the polarizer 120 blocks light in a specific direction and transmits light in a direction perpendicular to it.

In an embodiment, the polarizing layer 121 has an absorption axis and does not transmit linearly polarized light in the direction of the absorption axis, but allows light perpendicular to it to be transmitted.

In an embodiment, among the optical layers included in the light emitting display

device 10, layers excluding the polarizing layer 121 and the adhesive layer 130, that is, the positive C plate 111, the positive A plate 112, the negative A plate 113, and the negative C plate 122 may provide a phase difference to the transmitted light.

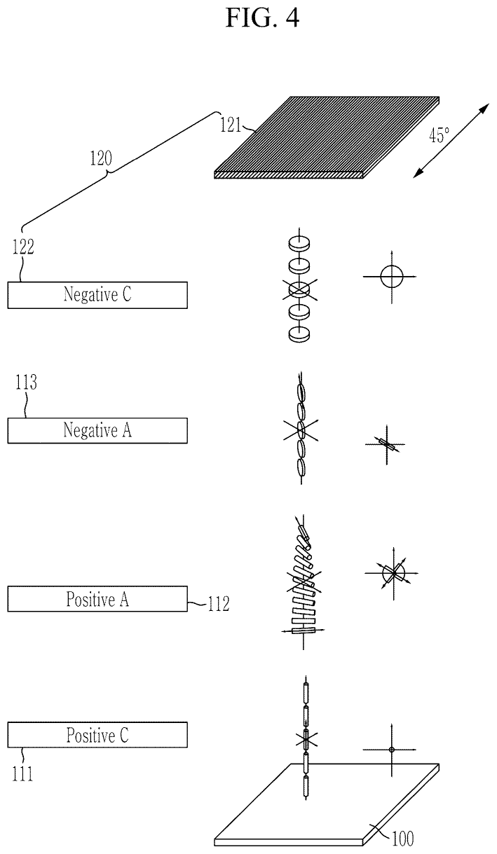

In an embodiment, the optical characteristics of the polarizing layer 121, the positive C plate 111, the positive A plate 112, the negative A plate 113, and the negative C plate 122 included in the optical layer are shown in FIGS. 4 to 12, and are shown in detail, and since the anisotropic characteristics are shown separately in FIG. 13, the structure of each optical layer will be examined in detail through FIGS. 4 to 13.

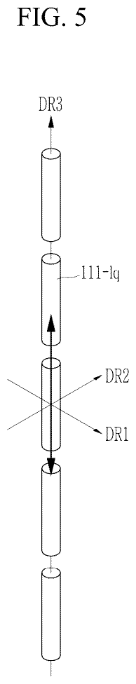

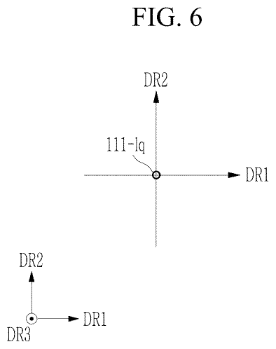

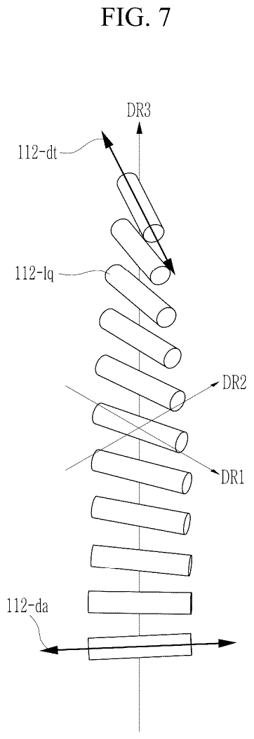

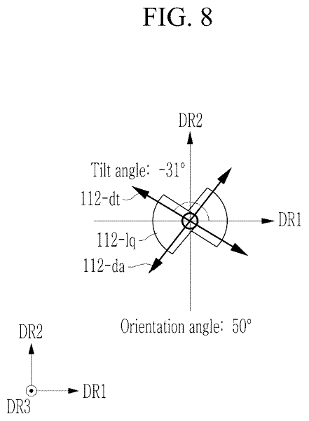

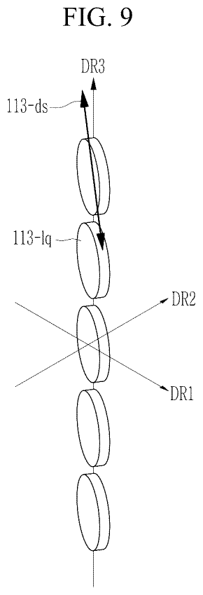

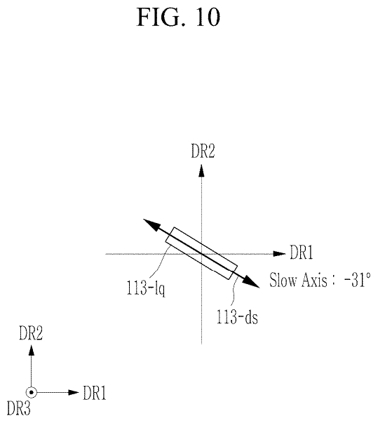

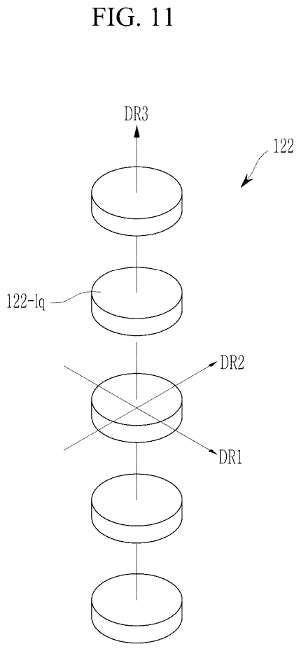

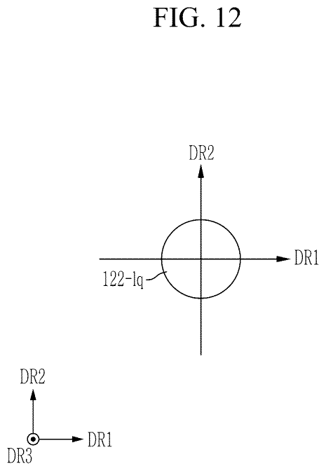

FIG. 4 is a diagram showing the specific structure of some of the optical layers of FIG. 3, according to an embodiment, FIGS. 5 and 6 are diagrams showing the structure of a positive C plate, according to an embodiment, and FIGS. 7 and FIG. 8 are diagrams showing the structure of a positive A plate, according to an embodiment, FIGS. 9 and 10 are diagrams showing the structure of a negative A plate, according to an embodiment, FIG. 11 is a diagram showing the structure of a positive A plate, according to an embodiment, and FIG. 12 is a diagram showing the structure of a negative C plate, according to an embodiment, while FIG. 13 is a diagram illustrating the anisotropic characteristics, according to an embodiment.

In an embodiment and referring to FIG. 5 to FIG. 12, the characteristics of the positive C plate 111, the positive A plate 112, the negative A plate 113, and the negative C plate 122 are shown, and in FIG. 4, the characteristics of the polarizing layer 121 are shown in conjunction with the features of FIG. 5 to FIG. 12.

In an embodiment and referring to FIG. 4, the polarizing layer 121 has an absorption axis having an angle of about 45 degrees with respect to the first direction DR1 and/or the second direction DR2 and transmits light in a direction perpendicular thereto.

In an embodiment, the polarizer 120 including the polarizing layer 121 and the negative C plate 122 may be formed in a film form, and the polarizer 120 may be formed with a structure that two film-shaped layers 122 and 123 are formed and attached on both sides of the polarizing layer 121 having a film form.

In an embodiment and referring to FIG. 13, the positive C plate 111 disposed closest to the display panel 100 among the optical layers has a refractive index (nx, ny, nz) for the three axes (x, y, z) of a “nz>nx=ny”.

In an embodiment, the three axes (x, y, z) are the three axes formed by the liquid crystal molecules constituting the positive C plate 111, and are directed in the first direction DR1 and the second direction DR2 according to the arrangement of the liquid crystal molecules, and may be the same as or different from the third direction DR3.

In an embodiment, in FIG. 5, the structure of the liquid crystal molecules 111-lq included in the positive C plate 111 is shown as viewed from the side, and in FIG. 6, the liquid crystal molecules 111-lq are viewed from above in the third direction DR3 (hereinafter referred to as the structure as seen from the front (also called front view) is shown.

In an embodiment, the shape of the liquid crystal molecule 111-lq is

shown as a shape corresponding to the size of the refractive index (nx, ny, nz).

In an embodiment, the liquid crystal molecule 111-lq of the positive C plate 111 has the highest refractive index (nz) with respect to the z-axis, and in FIG. 5, the liquid crystal molecule 111-lq has a long structure in the third direction DR3, so in the positive C plate 111, the z-axis of the liquid crystal molecules 111-lq and the third direction DR3 are directed in the same direction.

In an embodiment, the arrangement direction of the liquid crystal molecules 111-lq in the positive C plate 111 may differ from the third direction DR3 by approximately 10 degrees.

In an embodiment and referring to FIG. 6, since the liquid crystal molecule (111-lq) has the same refractive index (nx, ny) for the x-axis and y-axis, it can be confirmed that the cross-section of the liquid crystal molecule (111-lq) has a circular structure.

In an embodiment and referring to FIGS. 5 and 6, the liquid crystal molecules 111-lq included in the positive C plate 111 have a structure in which the z-axis is arranged in the third direction DR3.

In an embodiment, the positive C plate 111 can be formed by forming the liquid crystal molecules 111-lq in the arrangement direction described above.

In an embodiment, the positive C plate 111 can provide a phase difference of about −50 nm to about −85 nm as an Rth (out-of-plane retardation or thickness direction retardation) value to the transmitted light, and has an Ro (in-plane retardation) value close to about 0.

In an embodiment and referring to FIG. 13, the positive A Plate 112 disposed above the positive C Plate 111 has a relationship where the refractive indices (nx, ny, nz) for three axes (x, y, z) are “nx>ny=nz”.

In an embodiment, the three axes (x, y, z) are the three axes formed by the liquid crystal molecules constituting the positive A plate 112, and are directed in the first direction DR1 and the second direction DR2 according to the arrangement of the liquid crystal molecules, and may be the same as or different from the third direction DR3.

In an embodiment, in FIG. 7, the structure of the liquid crystal molecules 112-lq included in the positive A plate 112 is shown as viewed from the side, and in FIG. 8, the liquid crystal molecules 112-lq are viewed from above in the third direction DR3 (hereinafter referred to as the structure as seen from the front-also called front view) is shown.

In an embodiment, t, the shape of the liquid crystal molecule 112-lq is shown as a shape corresponding to the size of the refractive index (nx, ny, nz).

In an embodiment, t, the liquid crystal molecules 112-lq of the positive A plate 112 have the highest refractive index (nx) with respect to the x-axis, and in FIG. 7, the direction of the x-axis, which is the longest among the liquid crystal molecules 112-lq, is constant. Since it has a structure that rotates without rotation, the liquid crystal molecules (112-lq) have a twisted liquid crystal arrangement.

In an embodiment and referring to FIGS. 7 and 8, the liquid crystal molecule 112-lq having a twisted liquid crystal arrangement has an orientation angle 112-da and a tilt angle 112-dt.

In an embodiment and referring to FIG. 7, the alignment angle 112-da is the direction of the liquid crystal molecule 112-lq disposed at the bottom in the third direction DR3 among the plurality of liquid crystal molecules 112-lq included in the positive A plate 112, and the tilt angle 112-dt can be the direction of the liquid crystal molecule 112-lq disposed at the top in the third direction DR3 among the plurality of liquid crystal molecules 112-lq included in the positive A plate 112.

In an embodiment and referring to FIG. 8, the plurality of liquid crystal molecules 112-lq included in the positive A plate 112 have a twisted liquid crystal arrangement, and are therefore shown in a fan shape.

In an embodiment and referring to FIG. 8, the orientation angle 112-da of the liquid crystal molecules 112-lq of the positive A plate 112 is an angle of about 50 degrees with respect to the first direction DR1, and the tilt angle 112-dt may have an angle of about −31 degrees with respect to the first direction DR1.

In an embodiment, the orientation angle 112-da and tilt angle 112-dt of

the liquid crystal molecules 112-lq of the positive A plate 112 may differ from the angle of the present embodiment by less than about 10 degrees.

In an embodiment, the positive A plate 112 can be formed by forming the liquid crystal molecules 112-lq in the alignment direction described above.

In an embodiment, the positive A plate 112 can provide a phase

difference range of about 160 nm or more and about 180 nm or less as an Ro (in-plane retardation) value for the light that passes through, and has an Rth (out-of-plane retardation) value close to about 0.

In an embodiment, the negative A plate 113 disposed above the positive A plate 112 has a relationship of “nx<ny=nz” for the refractive index (nx, ny, nz) on three axes (x, y, z), as referred to in FIG. 13.

In an embodiment, the three axes (x, y, z) are the three axes formed by

the liquid crystal molecules constituting the negative A plate 113, and are directed in the first direction DR1 and the second direction DR2 according to the arrangement of the liquid crystal molecules, and may be the same as or different from the third direction DR3.

In an embodiment, in FIG. 9, the structure of the liquid crystal molecules 113-lq included in the negative A plate 113 is shown as viewed from the side, and in FIG. 10, the liquid crystal molecules 113-lq are viewed from above in the third direction DR3 (hereinafter referred to as the structure as seen from the front-also called front view) is shown.

In an embodiment, the shape of the liquid crystal molecule 113-lq is shown as a shape corresponding to the size of the refractive index (nx, ny, nz).

In an embodiment, the liquid crystal molecules (113-lq) of the negative A plate 113 have the smallest refractive index (nx) with respect to the direction is the slow axis (113-ds).

In an embodiment and referring to FIG. 10, the delay axis 113-ds of the liquid crystal molecule 113-lq may have an angle of about −31 degrees with respect to the first direction DR1.

In an embodiment, the direction of the delay axis 113-ds of the liquid crystal molecule 113-lq in the negative A plate 113 may differ from the angle described above by about 10 degrees.

In an embodiment, the negative A plate 113 can be formed by forming the liquid crystal molecules 113-lq in the alignment direction described above.

In an embodiment, the negative A plate 113 can provide a phase difference range of about −160 nm or more and less than about −180 nm to the light that penetrates, as an Ro (in-plane retardation) value, and has an Rth (out-of-plane retardation) value close to about 0.

In an embodiment, the negative C plate 122 included in the polarizer 120 and disposed below the polarizing layer 121 in the third direction DR3 may be formed in the form of a film attached to one side of the polarizing layer 121.

In an embodiment, the negative C plate 122 may also be formed by arranging liquid crystal molecules.

In an embodiment, the negative C plate 122 may be formed in a film form, but in order to easily examine it optically, its optical characteristics are examined using the shape of the liquid crystal molecule 122-lq in FIGS. 4, 11, and 12.

In an embodiment and referring to FIG. 13, the negative C plate 122 has a relationship of refractive indices (nx, ny, nz) with respect to three axes (x, y, z) of “nx=ny>nz”.

In an embodiment, the three axes (x, y, z) are the three axes formed by the liquid crystal molecules constituting the negative C plate 122, and are directed in the first direction DR1 and the second direction DR2 according to the arrangement of the liquid crystal molecules, and may be the same as or different from the third direction DR3.

In an embodiment, in FIG. 11, the structure of the liquid crystal molecule 122-lq corresponding to the optical properties of the negative C plate 122 is shown as viewed from the side, and in FIG. 12, the liquid crystal molecule 122-lq is shown in the third direction DR3, and the structure is shown as seen from above (hereinafter also referred to as the front).

In an embodiment, the shape of the liquid crystal molecule 122-lq is shown as a shape corresponding to the size of the refractive index (nx, ny, nz).

In an embodiment, the liquid crystal molecule 122-lq of the negative C plate 122 has the smallest refractive index (nz) with respect to the z-axis, and in FIG. 11, the liquid crystal molecule 122-lq has a short structure in the third direction DR3, so in the negative C plate 122, the z-axis of the liquid crystal molecule 122-lq and the third direction DR3 are in the same direction.

In an embodiment, the arrangement direction of the liquid crystal molecules 122-lq in the negative C plate 122 may differ from the third direction DR3 by approximately 10 degrees.

In an embodiment and referring to FIG. 12, the liquid crystal molecule 122-lq has the same refractive index (nx, ny) for the x-axis and y-axis, so it can be confirmed that the cross-section of the liquid crystal molecule 122-lq has a circular structure.

In an embodiment and referring to FIGS. 11 and 12, the liquid crystal molecules 122-lq corresponding to the negative C plate 122 have a structure in which the z-axis is arranged in the third direction DR3.

In an embodiment, the negative C plate 122 can provide a phase difference in a range of about 10 nm to about 50 nm as an Rth (out-of-plane retardation) value to the transmitted light, and has an Ro (in-plane retardation) value close to about 0.

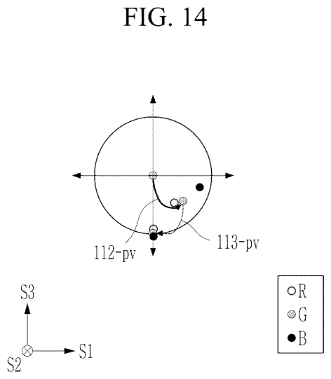

The optical characteristics of the light emitting display device 10 including an optical layer having the above optical characteristics will be examined through FIGS. 14 to 21.

FIGS. 14 to 21 are spherical coordinate diagrams shown to help understand polarization characteristics of the light emitting display device of FIG. 3, according to an embodiment.

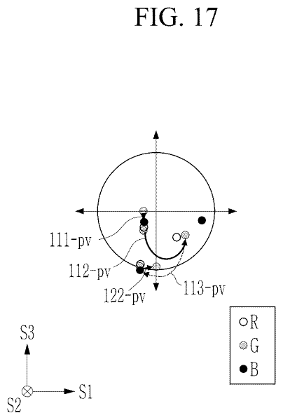

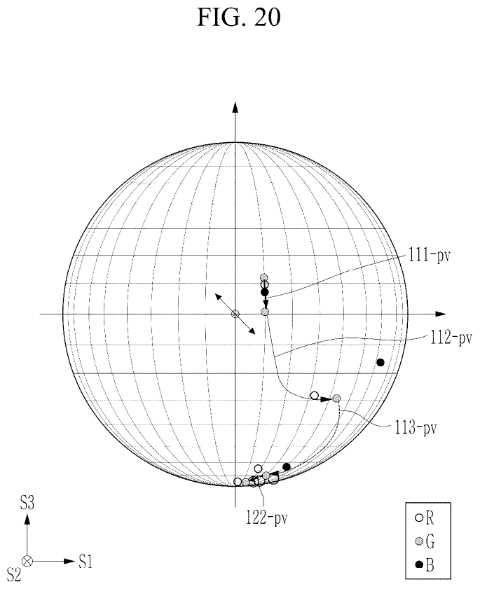

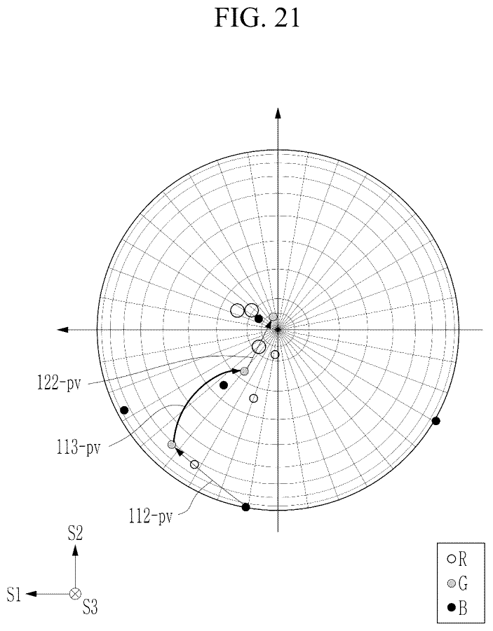

According to embodiments, FIGS. 14 to 16 show polarization characteristics when looking at the light emitting display device from the front (third direction DR3), and FIGS. 17 to 19 show polarization characteristics when viewed from the side at a certain angle from the front, FIGS. 20 and 21 show polarization characteristics viewed from a different side than those of FIGS. 17 to 19.

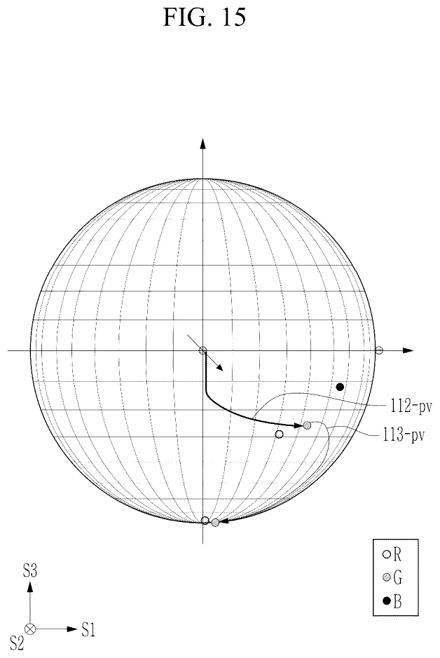

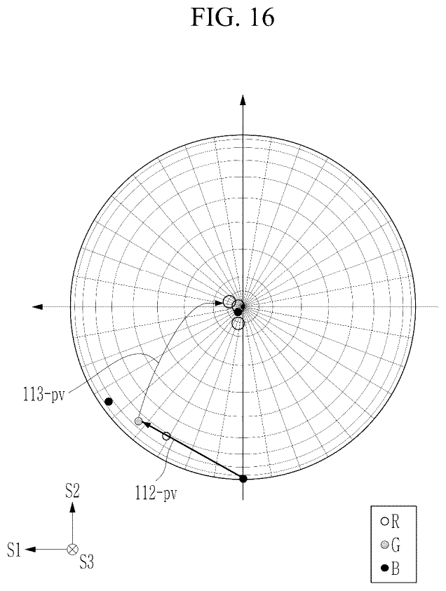

In an embodiment, FIG. 14 schematically shows polarization characteristics from the front, and FIGS. 15 and 16 show polarization characteristics from the front in detail.

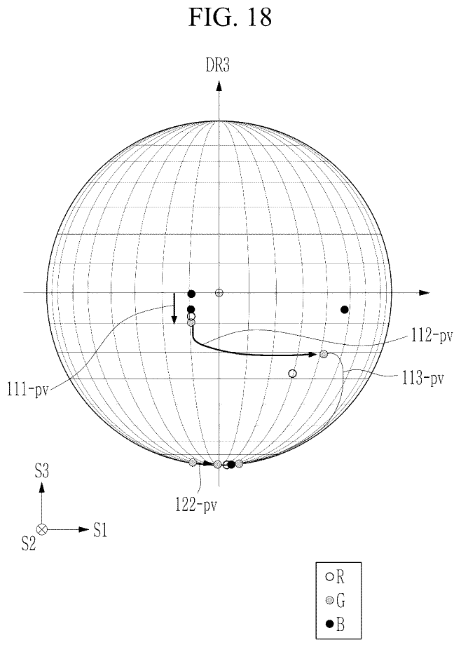

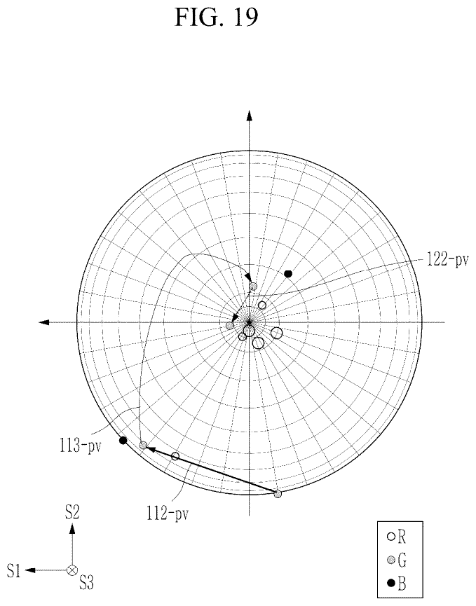

In an embodiment, FIG. 17 schematically shows polarization characteristics from the side, and FIGS. 18 and 19 show the polarization characteristics of FIG. 17 in detail.

In an embodiment, FIG. 14 to FIG. 21 show polarization characteristics through a spherical coordinate diagram, which is also called a Poincaré sphere, and which corresponds to the polarization state of a sphere with a radius of 1.

In an embodiment when the polarization characteristics of light are expressed as a 3×3 matrix, this matrix can also be expressed as a vector.

In an embodiment, if a vector showing the polarization characteristics of light is drawn in three-dimensional coordinates, the polarization characteristics can be displayed on a spherical coordinate diagram.

In an embodiment, in the spherical coordinate diagrams of FIGS. 14 to 21, there are three axes (S1, S2, and S3), each of which can represent a specific polarization direction.

In an embodiment, the direction opposite to the S3 axis represents the direction perpendicular to the absorption axis of the polarizing layer 121, that is, the direction corresponding to the transmission axis, considering that the polarization axis becomes the same axis when rotated 180 degrees, the direction of the S3 axis is S3, and since it is 90 degrees different from the direction opposite to the axis, the direction corresponding to the absorption axis of the polarizing layer 121 can be indicated.

In an embodiment, the directions of the S1 axis and the S2 axis may

indicate the direction of circular polarization, one of which may be left circular polarization and the other may be right circular polarization.

The change in polarization characteristics from the front (third direction DR3) are shown in FIGS. 14 to 16.

According to embodiments, FIG. 15 is a spherical coordinate diagram showing FIG. 14 in more detail, and FIG. 16 is a spherical coordinate diagram arranged so that the direction opposite to the S3 axis is disposed at the center, unlike FIGS. 14 and 15.

In an embodiment, FIGS. 14 to 16, polarization changes are shown through arrows, and although different polarization changes may appear for red (R), green (G), and blue (B), the arrows are centered on green (G).

In an embodiment, two arrows are indicated where each arrow represents the change in polarization characteristics by the positive A plate (112), referred to as the polarization change arrow of the positive A plate (112-pv), and the negative A plate (113), referred to as the polarization change arrow of the negative A plate (113-pv).

In an embodiment, it can be confirmed that there is almost no change in polarization due to the positive C plate 111 and the negative C plate 122 included in the optical layer.

Since this is a feature from the front, when viewed from the front as shown in FIGS. 6 and 12, according to an embodiment, the positive C plate 111 and the negative C plate 122 having circular cross-sections do not affect the change in polarization characteristics from the front.

Additionally, in an embodiment and referring to FIGS. 14 to 16, the final polarization characteristics that have passed through all optical layers are disposed in the opposite direction of the S3 axis.

In an embodiment and as shown in FIGS. 14 to 16, red (R), green (G), and blue (B) each have different wavelengths, so different changes in polarization characteristics may occur in the optical layer.

In an embodiment, since they are ultimately disposed in opposite directions to the S3 axis, it can be confirmed that the light emitting display device includes features that reduce the difference in polarization characteristics as a whole.

In an embodiment, all optical layers 111, 112, 113, and 122 having positive wavelength dispersion are used, but the optical layers 111, 112, 113, and 122 include negative wavelength dispersion as a whole, so that polarization characteristics depending on the wavelength are used, and the wavelength-dependent polarization characteristics, including the difference-reducing feature, are ultimately disposed in the opposite direction of the S3 axis.

More specifically, in an embodiment, the feature of negative wavelength dispersion may be disposed in the negative C plate 122 of the optical layers 111, 112, 113, and 122.

In an embodiment and referring to FIGS. 14 to 16, since the final polarization characteristics are all disposed in the opposite direction of the S3 axis, it can be seen that the difference in polarization characteristics depending on the wavelength at the front does not increase but decreases and can be disposed in the opposite direction of the S3 axis.

In an embodiment, the optical layers 111, 112, 113, and 122 that all have positive wavelength dispersion are used, but they have negative wavelength dispersion characteristics at the front due to the negative C plate 122, so that polarization characteristics depending on the wavelength are used, and it can be confirmed that it contains features that reduce the difference.

In an embodiment, the change in polarization characteristics from the side through FIGS. 17 to 21 is shown. In FIGS. 17 to 19, the angle is about 60 degrees with respect to the third direction (DR3), and the azimuth angle with respect to the first direction (DR1) is about 105 degrees, so it shows the polarization characteristics seen from the angle side.

In an embodiment, FIGS. 20 and 21 show polarization characteristics at a different side angle from FIGS. 17 to 19, and in FIGS. 20 and 21, the angle is about 60 degrees with respect to the third direction DR3, and the polarization characteristics are shown in the first direction (DR3), so it shows the polarization characteristics viewed from the side where the azimuth angle for (DR1) is about −15 degrees.

According to embodiments, FIG. 18 is a spherical coordinate diagram showing FIG. 17 in more detail, and FIG. 19 is a spherical coordinate diagram arranged so that the direction opposite to the S3 axis is disposed at the center, unlike FIGS. 17 and 18.

In an embodiment and referring to FIG. 17 to FIG. 19, polarization changes are shown through arrows, and although different polarization changes may appear for red (R), green (G), and blue (B), the arrows are centered on green (G).

As shown, four arrows are indicated, and the arrows are respectively an arrow showing the change in polarization characteristics due to the positive C plate 111 (111-pv; hereinafter also referred to as the polarization change arrow of the positive C plate) and the positive A plate 112, an arrow (112-pv; hereinafter also referred to as a polarization change arrow of the positive A plate) showing a change in polarization characteristics, an arrow (113-pv; hereinafter referred to as a polarization change arrow of the negative A plate 113 showing a change in polarization characteristics, also referred to as the polarization change arrow of the negative A plate), and an arrow showing the change in polarization characteristics due to the negative C plate 122 (122-pv; hereinafter also referred to as the polarization change arrow of the negative C plate).

Unlike FIGS. 14 to 16, since this is a polarization characteristic viewed from the side, in an embodiment, it can be confirmed that polarization changes also occur due to the positive C plate 111 and negative C plate 122 having circular cross-sections from the front.

Meanwhile, looking at FIGS. 20 and 21, they are as follows.

Unlike FIG. 20, FIG. 21 is a spherical coordinate diagram arranged so that the direction opposite to the S3 axis is disposed at the center, according to an embodiment.

In an embodiment and referring to FIGS. 20 and 21, a total of four arrows (111-pv, 112-pv, 113-pv, 122-pv) are shown, similar to the change in polarization characteristics of FIGS. 17 to 19, except for the direction in which the polarization characteristics change, and it can be seen that this is different from FIGS. 17 to 19.

In an embodiment and referring to FIGS. 17 to 21, it is preferable that the final polarization characteristics are directed in the opposite direction to the S3 axis in all directions, but the polarization direction on the side may be slightly deviated from the direction opposite to the S3 axis, so that it is transmitted through the polarizing layer 121, it may not be absorbed and some of it may be absorbed.

In an embodiment and referring to FIGS. 17 to 21, the final polarization characteristics are disposed adjacent to the opposite direction of the S3 axis, and are smaller than the difference in polarization characteristics of red (R), green (G), and blue (B) at the intermediate position where polarization changes, and it can be seen that the difference in polarization characteristics of each color at the final polarization position is reduced.

In an embodiment, optical layers 111, 112, 113, and 122 having positive wavelength dispersion on all sides are used, but the optical layers 111, 112, 113, and 122 have negative wavelength dispersion as a whole, so that polarization according to the wavelength is used, and it can be confirmed that it contains features that reduce the difference in characteristics.

More specifically, in an embodiment, the feature of negative wavelength dispersion may be disposed in the negative C plate 122 of the optical layers 111, 112, 113, and 122.

In an embodiment and referring to FIGS. 17 to 21, since the final polarization characteristics are all disposed near the opposite direction of the S3 axis, it can be seen that the difference in polarization characteristics depending on the wavelength on the side does not increase but decreases and can be disposed in the opposite direction of the S3 axis.

Therefore, in an embodiment, the optical layers 111, 112, 113, and 122 all have positive wavelength dispersion, but have negative wavelength dispersion characteristics on the side due to the negative C plate 122, so that the polarization characteristics according to the wavelength are used, and it can be confirmed that it contains features that reduce the difference.

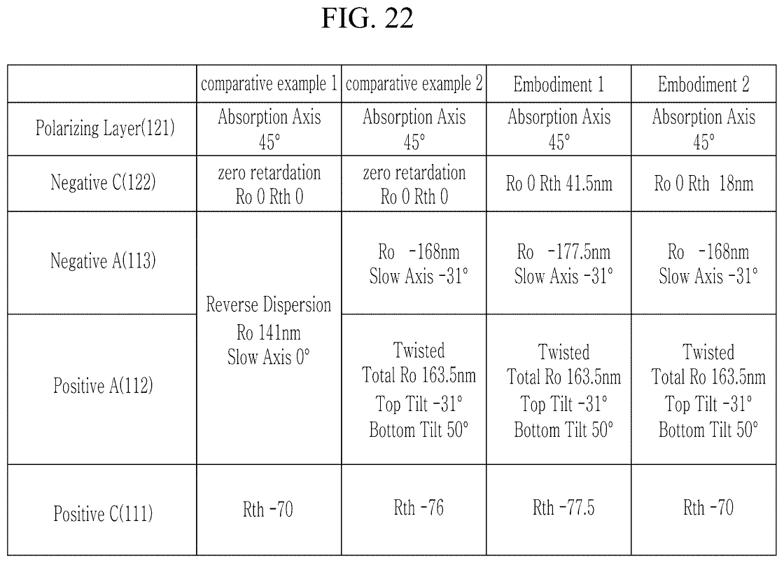

Hereinafter, the characteristics of an embodiment will be examined through comparison with the comparative example through FIGS. 22 to 30.

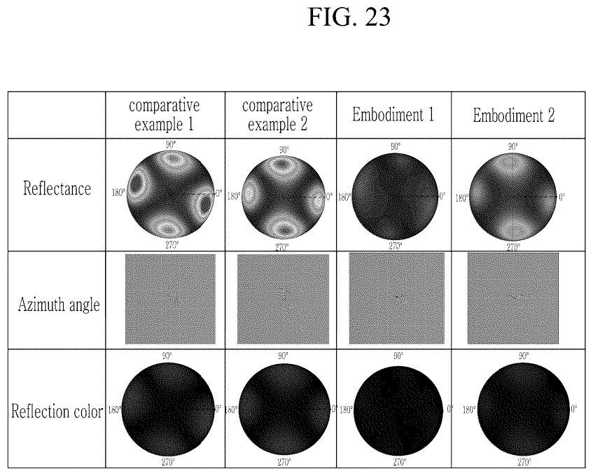

First, look at FIG. 22 and FIG. 23.

FIGS. 22 and 23 are diagrams showing the structure and reflection characteristics of comparative examples according to embodiments.

In an embodiment, in FIG. 22, the characteristics of the optical layers 111, 112, 113, 122 and the polarizing layer 121 of comparative example 1, comparative example 2, embodiment 1, and embodiment 2 are shown in a table, and FIG. 23 shows the characteristics of each comparative example and the results of simulating the reflection characteristics of the embodiment.

In an embodiment and referring to FIG. 22, in Example 1, the polarizing layer 121 has an absorption axis having an angle of about 45 degrees with respect to the first direction DR1 and/or the second direction DR2, and is a negative C plate. The polarizing layer 121 provides a phase difference of about 41.5 nm as an Rth (out-of-plane retardation) value to the transmitted light, and has an Ro (in-plane retardation) value close to about 0.

In an embodiment, the negative A plate 113 provides a phase difference of about −177.5 nm as an Ro (in-plane retardation) value for the light that penetrates, and the delay axis (113-ds; slow axis) of the liquid crystal molecules (113-lq) included in the negative A plate 113 has an angle of about −31 degrees with respect to the first direction DR1.

In addition, in an embodiment, the positive A plate 112 provides a phase difference of 163.5 nm as the Ro (in-plane retardation) value to the transmitted light, and the orientation of the liquid crystal molecules 112-lq of the positive A plate 112 112-da (Bottom Tilt) has an angle of about 50 degrees with respect to the first direction DR1, while the tilt angle 112-dt (top tilt) has an angle of about −31 degrees with respect to the first direction DR1.

In addition, in an embodiment, the positive C plate 111 provides a phase difference of about −77.5 nm as an Rth (out-of-plane retardation) value to the transmitted light.

In an embodiment and referring to FIG. 22, in embodiment 2, the polarizing layer 121 has an absorption axis having an angle of about 45 degrees with respect to the first direction DR1 and/or the second direction DR2, and the negative C plate 122 is transparent, and provides a phase difference of about 18 nm as an Rth (out-of-plane retardation) value to the light, and has an Ro (in-plane retardation) value close to about 0.

In addition, in an embodiment, the negative A plate 113 provides a phase difference of about −168 nm as the Ro (in-plane retardation) value to the transmitted light, and in the liquid crystal molecules (113-lq) contained in the negative A plate 113, the delay axis 113-ds has an angle of about −31 degrees with respect to the first direction DR1.

In addition, in an embodiment, the positive A plate 112 provides a phase difference of about 163.5 nm as the Ro (in-plane retardation) value to the transmitted light, and in the orientation of the liquid crystal molecules 112-lq of the positive A plate 112, the angle 112-da has an angle of about 50 degrees with respect to the first direction DR1, while the tilt angle 112-dt is an angle of about −31 degrees with respect to the first direction DR1.

In addition, in an embodiment, the positive C plate 111 provides a phase difference of about −70 nm as an Rth (out-of-plane retardation) value to the transmitted light.

In an embodiment and referring to FIG. 22, comparative examples 1 and 2 do not include the negative C plate 122 disposed below the polarizing layer 121, so that an Rth (out-of-plane retardation or thickness direction retardation) and an Ro (in-plane retardation) values are 0 (zero retardation).

Additionally, in an embodiment, comparative example 1 differs in that a plate with negative wavelength dispersion is disposed at the position of the positive C plate 111 and the positive A plate 112.

In FIG. 22, embodiments of the angles of each optical layer 111, 112, 113, and 122 and the polarizing layer 121 are clearly described.

The results of simulating reflection characteristics for the comparative examples and examples shown in FIG. 22 are shown in FIG. 23, according to an embodiment.

In an embodiment and referring to FIG. 23, it can be seen that

embodiments 1 and 2 have lower reflectance compared to comparative examples 1 and 2, and there is little difference in the overall reflection color characteristics.

Here, embodiments 1 and 2 had a value lower than about 10% even in the parts where the front reflectance had the maximum value, and in the comparative examples, many parts had a front reflectance exceeding about 10%.

Therefore, it can be confirmed that a feature of an embodiment is that the front reflectance of external light has a value of about 10% or less.

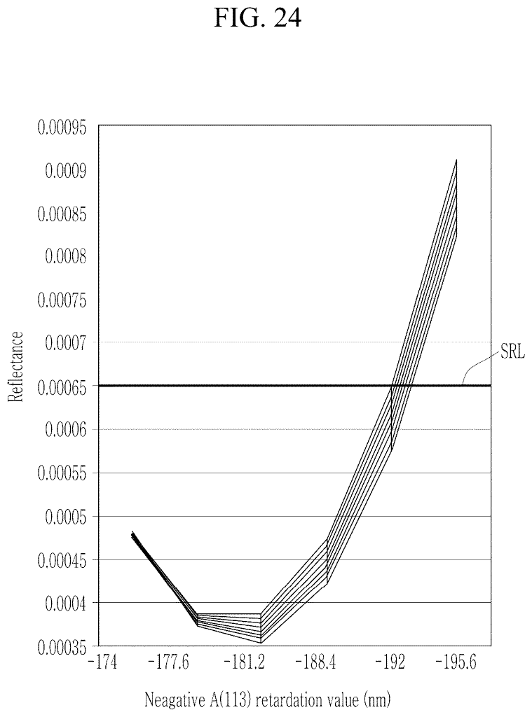

In an embodiment, in FIG. 23, the overall reflection characteristics of the light emitting display device are examined, and below, the characteristics of the reflectance according to the retardation value provided by some optical layers are examined through FIGS. 24 to 27.

FIGS. 24 to 27 are graphs showing reflection characteristics depending on the angle of some plates included in the optical layer, according to embodiments.

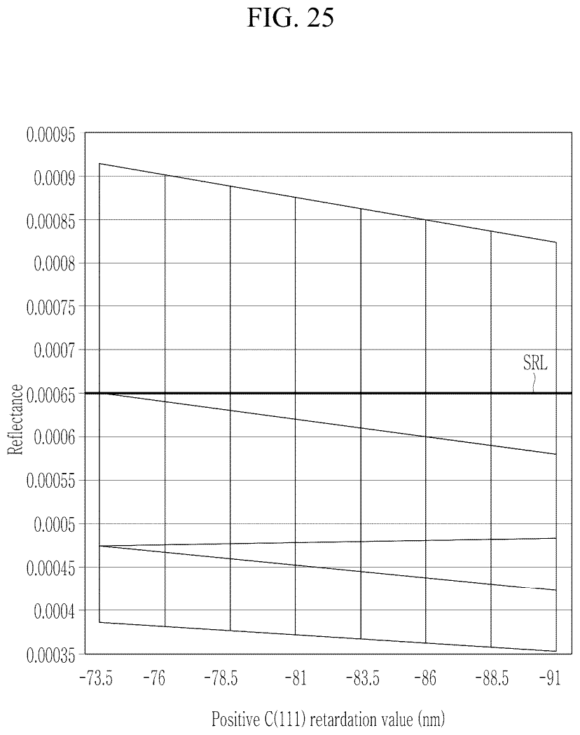

In an embodiment, FIGS. 24 and 25 are measured from the front, that is, in the third direction DR3, where in FIG. 24, a graph of the reflectance from the front is shown against the retardation value provided by the negative A plate 113, FIG. 25 shows a graph of the reflectance from the front versus the retardation value provided by the positive C plate 111.

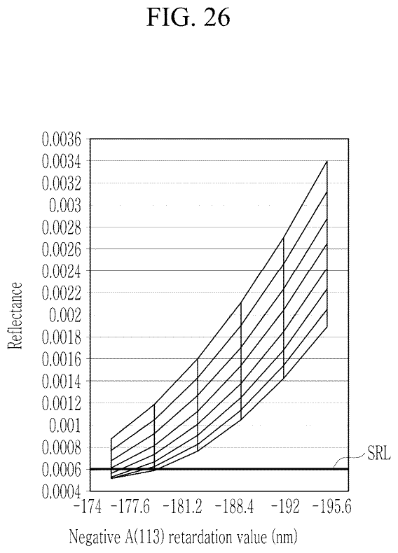

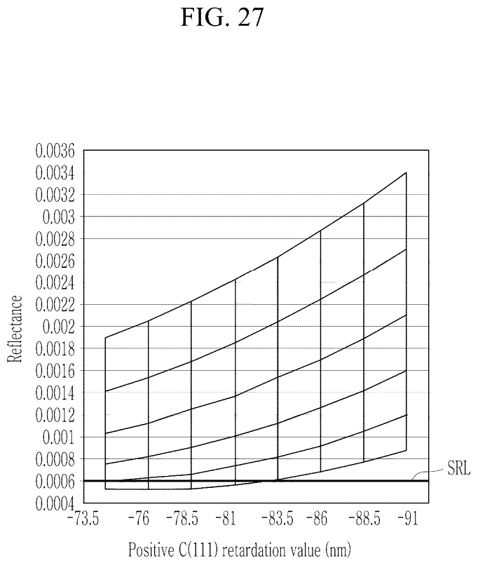

In an embodiment, FIGS. 26 and 27 are measured from the side having an angle of about 60 degrees with respect to the third direction (DR3) and an azimuth angle of about 135 degrees with respect to the first direction (DR1), in FIG. 26, the negative A plate 113 is a graph of the reflectance on the corresponding side relative to the retardation value provided is shown, and in FIG. 27, a graph of the reflectance on the corresponding side relative to the retardation value provided by the positive C plate 111 is shown.

In an embodiment and referring to FIG. 24 to FIG. 27, a thick horizontal line shows a location where the reflectance is 0.00065%. This thick horizontal line represents the reference reflectance (SRL), and only the retardation value that provides lower reflectance than SRL can be applied to the embodiment.

In an embodiment, this reference reflectance (SRL) can be set in various ways depending on the location where the light emitting display device is used.

In an embodiment and referring to FIG. 25 to FIG. 27, some of the simulation result graphs are shown to be higher than the overall Standard Reflection Level (SRL), and this is because the graphs are duplicated depending on various variables considered during the simulation. From here on, examination is based on the graph with the lowest reflectivity.

First, look at the negative A plate 113 through FIGS. 24 and 26.

In an embodiment and referring to FIG. 24, in order to have a standard reflectance (SRL) or less from the front, the retardation provided by the negative A plate 113 may have a value range of about −174 nm or more and about −192 nm or less.

In an embodiment and referring to FIG. 26, in order to have a reference reflectance (SRL) or less at the corresponding side angle, the retardation provided by the negative A plate 113 may have a value range of about −174 nm or more and about −177.6 nm or less.

In an embodiment, considering the trend of the graphs in FIGS. 24 and 26, even if the value is lower than about −174 nm, it appears to be sufficiently below the standard reflectance (SRL), so it is judged that it can have a retardation value of about −160 nm or more. When considering the front as the center, in order to have lower reflectance than the standard reflectance (SRL), it is judged that a retardation value of about −180 nm or less can be achieved.

The negative A plate 113, according to an embodiment, may have a in-plane retardation value of about −160 nm or more and about −180 nm or less.

Referring to FIGS. 25 and 27, the positive C plate 111 is shown according to an embodiment.

In an embodiment and referring to FIG. 25, in order to have a standard reflectance (SRL) or less from the front, the retardation provided by the positive C plate 111 may have a value range of about −73.5 nm or more and about −91 nm or less. In an embodiment and referring to FIG. 27, in order to have a reference

reflectance (SRL) or less at the corresponding side angle, the retardation provided by the positive C plate 111 may have a value range of about −73.5 nm or more and about −83.5 nm or less.

In an embodiment, considering the trend of the graphs in FIGS. 25 and 27, even if the value is lower than about −73.5 nm, it appears to be sufficiently below the standard reflectance (SRL), so it is judged that it can have a retardation value of about −50 nm or more, and when considering the front as the center, it is judged that in order to have reflectance below the standard reflectance (SRL), a retardation value of about −85 nm or less can be achieved.

The positive C plate 111, according to an embodiment, may have an in-plane retardation value of about −50 nm to about −85 nm.

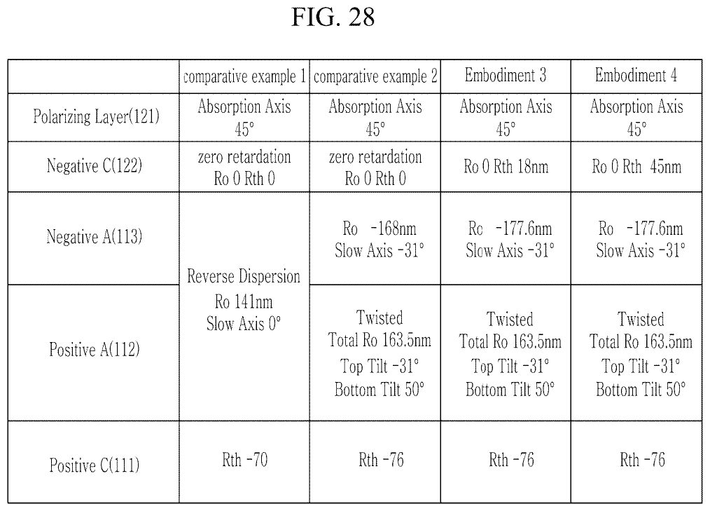

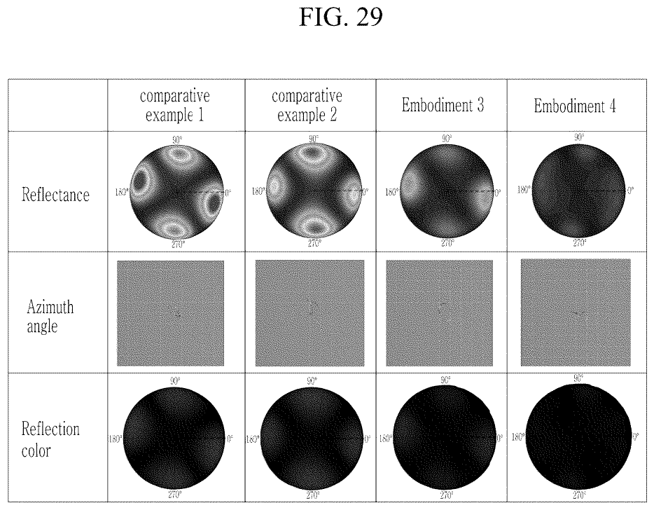

The following corresponds to embodiments in FIGS. 22 and 23, and Embodiment 3 and Embodiment 4 will be examined with regards to FIGS. 28 and 29.

FIG. 28 and FIG. 29 are diagrams showing the structure and reflection characteristics of comparative examples and some embodiments.

In an embodiment, comparative example 1 and comparative example 2 shown in FIG. 28 are the same as comparative example 1 and comparative example 2 shown in FIG. 22, FIG. 28 illustrates the features of the optical layers (111, 112, 113, 122) and the polarizing layer 121 of comparative example 1, comparative example 2, embodiment 3, and embodiment 4 in a table, and FIG. 29 shows the results of simulating the reflective characteristics of each comparative example, embodiment 3 and embodiment 4.

In an embodiment and referring to FIG. 28, the angles of each optical layer (111, 112, 113, 122) and the polarizing layer 121 are clearly described, and the results of simulating the reflection characteristics for comparative examples and embodiments 3 and 4 like those shown in FIG. 28 are shown in FIG. 29.

In an embodiment and referring to FIG. 28, in embodiment 3, the polarizing layer 121 has an absorption axis having an angle of about 45 degrees with respect to the first direction DR1 and/or the second direction DR2, and is a negative C plate 122. The negative C plate 122 provides a phase difference of about 18 nm as an Rth (out-of-plane retardation) value to the transmitted light, and has an Ro (in-plane retardation) value close to about 0.

In addition, in an embodiment, the negative A plate 113 provides a phase difference of about −177.6 nm as an Ro (in-plane retardation) value to the transmitted light, and the liquid crystal molecules (113-lq) contained in the negative A plate's 113 delay axis (113-ds; slow axis) has an angle of about −31 degrees with respect to the first direction (DR1).

In an embodiment, the positive A plate 112 provides a phase difference of about 163.5 nm as an Ro (in-plane retardation) value to the transmitted light, and the orientation of the liquid crystal molecules 112-lq of the positive A plate 112. The angle 112-da (Bottom Tilt) has an angle of about 50 degrees with respect to the first direction DR1, and the tilt angle 112-dt (Top Tilt) has an angle of about −31 degrees with respect to the first direction DR1.

In an embodiment, the positive C plate 111 provides a phase difference of about −76 nm as an Rth (out-of-plane retardation) value to the transmitted light.

Referring to FIG. 28, in Embodiment 4, the polarizing layer 121 has an

absorption axis having an angle of about 45 degrees with respect to the first direction DR1 and/or the second direction DR2, and the negative C plate 122 is transparent, so a phase difference of about 45 nm is provided as an Rth (out-of-plane retardation) value to the light, and has an Ro (in-plane retardation) value close to about 0.

In an embodiment, the negative A plate 113 provides a phase difference of about −177.6 nm as an Ro (in-plane retardation) value to the transmitted light, and the liquid crystal molecules (113-lq) contained in the negative A plate 113) of the delay axis 113-ds have an angle of about −31 degrees with respect to the first direction DR1.

In an embodiment, the positive A plate 112 provides a phase difference of about 163.5 nm as an Ro (in-plane retardation) value to the transmitted light, and in the orientation of the liquid crystal molecules 112-lq of the positive A plate 112, the angle 112-da is an angle of about 50 degrees with respect to the first direction DR1, and the tilt angle 112-dt is an angle of about −31 degrees with respect to the first direction DR1.

In an embodiment, the positive C plate 111 provides a phase difference of about −76 nm as an Rth (out-of-plane retardation) value to the transmitted light.

In an embodiment and referring to FIG. 28, the difference between embodiment 3 and embodiment 4 is only an Rth (out-of-plane retardation) value provided by the negative C plate 122, and the remaining optical layer and the polarizing layer have characteristics that are set identically.

In an embodiment and referring to FIG. 29, it can be seen that Embodiments 3 and 4 have lower reflectance than comparative examples 1 and 2, and there is little difference in the overall reflection color characteristics.

Embodiments 3 and 4 had a value that is lower than about 10% even in the parts where the front reflectance had the maximum value, and in the comparative examples, many parts had front reflectance exceeding about 10%.

It can be confirmed that a feature of an embodiment is that the front reflectance has a value of about 10% or less.

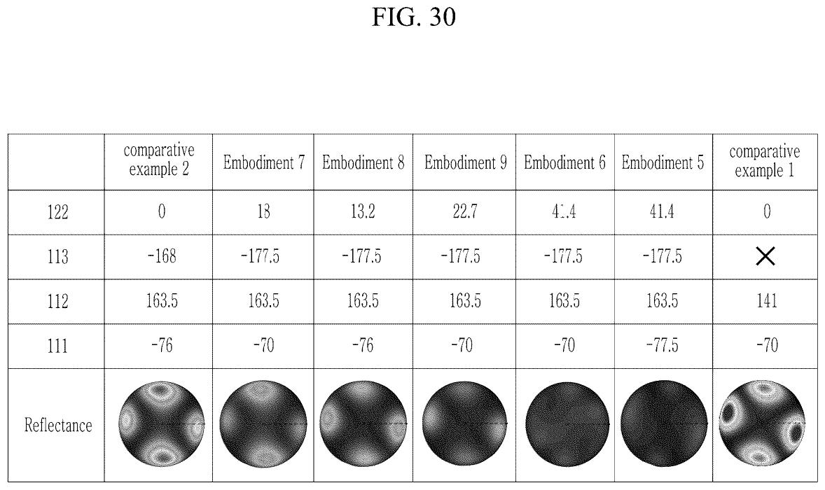

In an embodiment, the reflectance characteristics of additional embodiments along with comparative examples 1 and 2 are shown in FIG. 30.

FIG. 30 is a diagram showing reflection characteristics of comparative examples and various embodiments.

FIG. 30 shows the reflection characteristics of Embodiments 5 to 9,which are similar to embodiments 1 to 4 described above, but the retardation values provided by each optical layer were slightly changed.

The retardation values provided in Embodiments 5 to 9 are as follows, and the angles of the optical layer are the same as those of embodiments 1 to 4.

In embodiment 5, the negative C plate 122 provides a phase difference of about 41.4 nm as an Rth (out-of-plane retardation) value to the transmitted light, and the negative A plate 113 provides an Ro (in-plane retardation) value to the transmitted light, and it provides a phase difference of about −177.5 nm as a Ro (in-plane retardation) value, while the positive A plate 112 provides a phase difference of about 163.5 nm as an Ro (in-plane retardation) value to the transmitted light, the positive C plate 111 provides a phase difference of about −77.5 nm as an Rth (out-of-plane retardation) value to the transmitted light.

In embodiment 6, the negative C plate 122 provides a phase difference of about 41.4 nm as an Rth (out-of-plane retardation) value to the transmitted light, and the negative A plate 113 provides an Ro to the transmitted light, where it provides a phase difference of about −177.5 nm as an in-plane retardation value, and the positive A plate 112 provides a phase difference of about 163.5 nm as an Ro (in-plane retardation) value to the transmitted light, while the positive C plate 111 provides a phase difference of about −70 nm as an Rth (out-of-plane retardation) value to the transmitted light.

In Embodiment 7, the negative C plate 122 provides a phase difference of about 18 nm as an Rth (out-of-plane retardation) value to the transmitted light, and the negative A plate 113 provides Ro (Ro) to the transmitted light, and it provides a phase difference of about −177.5 nm as an in-plane retardation value, and the positive A plate 112 provides a phase difference of about 163.5 nm as an Ro (in-plane retardation) value to the transmitted light, while the positive C plate 111 provides a phase difference of about −70 nm as an Rth (out-of-plane retardation) value to the transmitted light.

In Embodiment 8, the negative C plate 122 provides a phase difference of about 13.2 nm as an Rth (out-of-plane retardation) value to the transmitted light, and the negative A plate 113 provides an Ro to the transmitted light, and it provides a phase difference of about −177.5 nm as an in-plane retardation value, and the positive A plate 112 provides a phase difference of about 163.5 nm as an Ro (in-plane retardation) value to the transmitted light, while the positive C plate 111 provides a phase difference of about −76 nm as an Rth (out-of-plane retardation) value to the transmitted light.

In Embodiment 9, the negative C plate 122 provides a phase difference of about 22.7 nm as an Rth (out-of-plane retardation) value to the transmitted light, and the negative A plate 113 provides an Ro to the transmitted light, and it provides a phase difference of about −177.5 nm as an in-plane retardation value, and the positive A plate 112 provides a phase difference of about 163.5 nm as an Ro (in-plane retardation) value to the transmitted light, while the positive C plate 111 provides a phase difference of about −70 nm as an Rth (out-of-plane retardation) value to the transmitted light.

Referring to FIG. 30, it can be seen that a feature of the embodiments is that the front reflectance has a value of about 10% or less.

In an embodiment, the negative C plate 122 disposed below the polarizing layer 121 may be formed in a film form and may be attached to the lower part of the polarizing layer 121.

Meanwhile, in some embodiments, the positive C plate 111, the positive A plate 112, and the negative A plate 113 included in the optical layer can be formed by arranging liquid crystal molecules included in each in specific directions. However, the invention is not limited to these embodiments.

In an embodiment, a method of forming a film to have a phase difference includes forming the material constituting the film into a film and stretching it in a specific direction to have a phase difference in a specific direction.

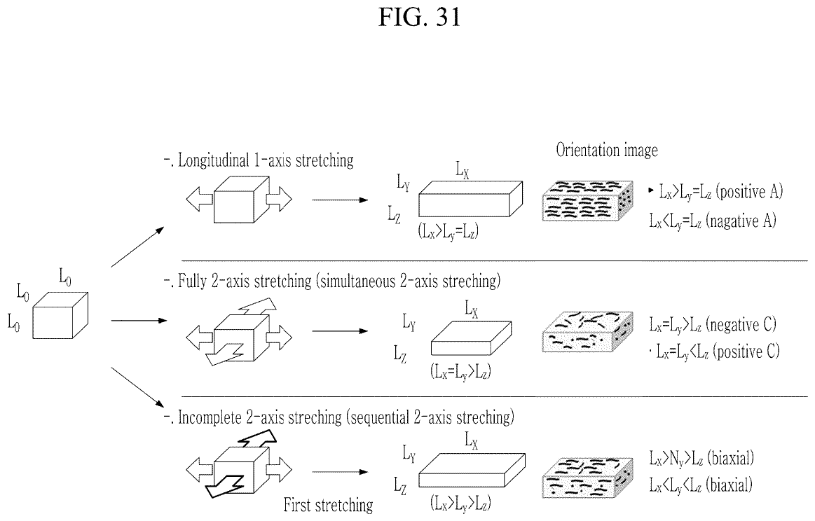

The method of creating a phase difference in the form of a film is shown in detail in FIG. 31, according to an embodiment.

FIG. 31 is a diagram showing various optical properties of the film, according to stretching, according to an embodiment.

In an embodiment and referring to FIG. 31, it is shown that the optical properties are determined by the size of the refractive index (nx, ny, nz) by continuously changing the length (Lx, Ly, Lz) of each axis for a film material with the same length (L0).

In an embodiment, there can be a variety of methods for providing a phase difference by arranging liquid crystal molecules, and there are two main methods: a rubbing method that arranges liquid crystal molecules in a rubbing direction and a photo-alignment method that uses light to align liquid crystal molecules in a specific direction.

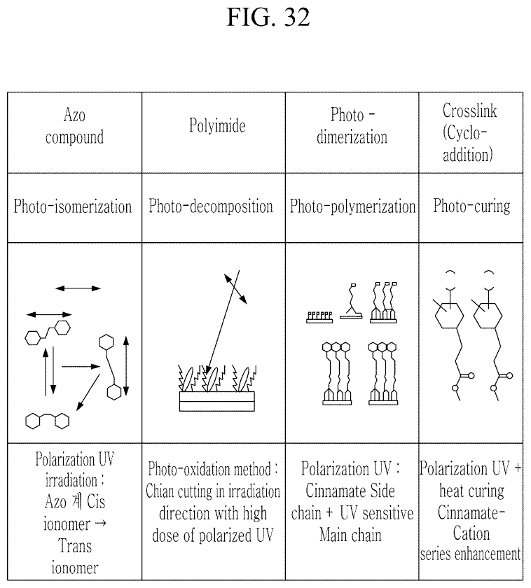

In an embodiment, the rubbing method can be simple because the liquid crystal molecules can be aligned in the direction of the rubbing, in another embodiment various photo-alignment methods also exist as shown in FIG. 32.

FIG. 32 is a diagram illustrating various examples of photo-alignment, according to embodiments.

In an embodiment and referring to FIG. 32, photo-alignment methods can be broadly divided into photo-isomerization methods, photo-decomposition methods, photo-polymerization methods, and photo-curing methods.

In an embodiment, the photo-isomerization method can use an azo compound, and when irradiated with polarized ultraviolet (UV) light, the ionomer changes from a cis-type molecular structure to a trans-type molecular structure, and as it changes, it allows the liquid crystal molecules to be arranged accordingly.

In an embodiment, the photo-decomposition method can also be called a photooxidation method and uses polarized ultraviolet (UV) light to cut polyimide chains so that liquid crystal molecules can be arranged in a specific direction.

In an embodiment, the photo-polymerization method can use materials capable of photo-dimerization and uses polarized ultraviolet (UV) cinnamate as a side chain to connect them to each other, and the main chain is photopolymerized to be sensitive to ultraviolet rays so that the liquid crystal molecules can be arranged accordingly.

In an embodiment, the light curing method uses polarized ultraviolet (UV) light to heat cure it so that the liquid crystal molecules are aligned in specific directions, and materials with crosslinks (cyclo-addition) can be used, a material containing a cinnamate portion that reacts and combines with UV and a positive charge (cation) portion that reacts and combines with heat can be used.

In an embodiment, liquid crystal molecules can be aligned in a specific direction through photoreaction and thermal curing.

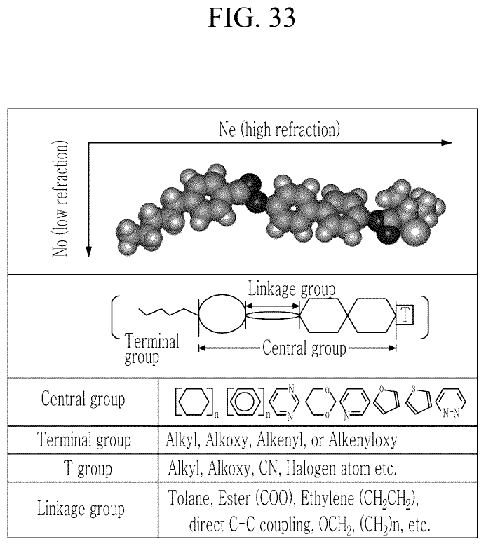

In an embodiment, among the liquid crystal molecules included in the optical layer, certain liquid crystal molecules may have a rod shape, and hereinafter, various examples of rod-shaped liquid crystal molecules will be examined using FIG. 33.

FIG. 33 is a diagram illustrating various examples of rod-structured liquid crystal molecules, according to an embodiment.

In an embodiment, the rod-shaped liquid crystal molecule may have a different refractive index depending on the direction, may have a chemical structure as described in the second row, and one of the materials disposed in the third to sixth rows may be used.

In an embodiment, when classifying rod-shaped liquid crystal molecules based on their chemical formulae, they include a central group containing an aromatic compound and a linkage group connecting them, and terminal groups on both sides of the central group (terminal group) and the T group.

In an embodiment, examples of compounds that can be placed in each group are shown in FIG. 33.

In an embodiment, the length and/or viscosity properties of the rod-shaped liquid crystal molecule are related to the terminal group and/or linkage group, and the refractive index and refractive index anisotropy properties are related to the central group, and the polarity that affects the crystal phase can be related to the T group.

In particular, in wavelength dispersion, the short-wavelength refractive index tends to increase depending on the central group content, and the wavelength dispersion characteristics can be adjusted depending on the ratio of the central group and the terminal group, according to embodiments.

Although embodiments have been described in detail above, the scope of the invention is not limited thereto, and various modifications and improvements can be made by those skilled in the art using the basic concepts of the present invention. Embodiments of the invention disclosed herein and illustrated in the drawings are provided as particular examples for more easily explaining the technical contents according to the invention and helping understand the embodiments of the invention, but they not intended to limit the scope of the invention. Accordingly, the scope of the invention should be interpreted to include, in addition to embodiments disclosed herein, all alterations or modifications derived from the technical ideas of the various embodiments. Moreover, the embodiments or parts of the embodiments may be combined in whole or in part without departing from the scope of the invention.

1. A light emitting display device, comprising:
a display panel including light emitting diodes;
a positive C plate disposed in front of the display panel;
a positive A plate disposed in front of the positive C plate;
a negative A plate disposed in front of the positive A plate; and
a polarizer disposed in front of the negative A plate,
wherein the polarizer includes:
a polarizing layer having an absorption axis; and
a negative C plate disposed between the polarizing layer and the negative A plate,
wherein the positive C plate, the positive A plate, the negative A plate, and the negative C plate each have positive wavelength dispersion characteristics, and wherein the light emitting display device has negative wavelength dispersion characteristics at a front as a whole.

2. The light emitting display device of claim 1, wherein
the light emitting display device has front reflectance of external light of about 10% or less.

3. The light emitting display device of claim 2, wherein
the positive C plate, the positive A plate, and the negative A plate are formed by arranging liquid crystal molecules, and
wherein the negative C plate is in the form of a film and is attached to one side of the polarizing layer.

4. The light emitting display device of claim 3, wherein
the positive C plate has a thickness direction retardation value in a range of about −50 nm or more and about −85 nm or less.

5. The light emitting display device of claim 3, wherein
the positive A plate is a light emitting display device having a front has an in-plane retardation value in the range of about 160 nm or more and about 180 nm or less.

6. The light emitting display device of claim 5, wherein
the liquid crystal molecules included in the positive A plate have a twisted liquid crystal arrangement, and
wherein the twisted liquid crystal molecules of the positive A plate have an orientation angle of about 50 degrees with respect to the first direction and a tilt angle of about −31 degrees with respect to the first direction.

7. The light emitting display device of claim 3, wherein
the negative A plate is a light emitting display device having a front has an in-plane retardation value in the range of about −160 nm or more and about −180 nm or less.

8. The light emitting display device of claim 7, wherein
the negative A plate has a delay axis and has an angle of about −31 degrees with respect to the first direction.

9. The light emitting display device of claim 3, wherein
the negative C plate has a thickness direction retardation value in a range of about 10 nm to about 50 nm.

10. The light emitting display device of claim 1, wherein
the absorption axis of the polarizing layer has an angle of about 45 degrees with respect to the first direction.

11. The light emitting display device of claim 1, further comprising,
an adhesive layer disposed between the positive A plate and the negative A plate, and between the negative A plate and the polarizer.

12. A light emitting display device, comprising:
a display panel including light emitting diodes;
a positive C plate disposed in front of the display panel;
a positive A plate disposed in front of the positive C plate;
a negative A plate disposed in front of the positive A plate; and
a polarizer disposed in front of the negative A plate,
wherein the polarizer includes
a polarizing layer having an absorption axis, and
a negative C plate disposed between the polarizing layer and the negative A plate,
wherein the positive C plate has a thickness direction retardation value in a range of about −50 nm to about −85 nm,
the positive A plate has an in-plane retardation value in a range of about 160 nm or more and about 180 nm or less,
the negative A plate has an in-plane retardation value in a range of about −160 nm to about −180 nm, and
the negative C plate has a thickness direction retardation value in a range of about 10 nm to about 50 nm.

13. The light emitting display device of claim 12, wherein
the positive C plate is formed by aligning liquid crystal molecules.

14. The light emitting display device of claim 12, wherein
the positive A plate is formed by twisting liquid crystal molecules, and
wherein the twisted liquid crystal molecules of the positive A plate have an orientation angle of about 50 degrees with respect to the first direction and a tilt angle of about −31 degrees with respect to the first direction.

15. The light emitting display device of claim 12, wherein
the negative A plate is formed by arranging liquid crystal molecules, wherein
the negative A plate has a delay axis and has an angle of about −31 degrees with respect to the first direction.

16. The light emitting display device of claim 12, wherein
the negative C plate is in the form of a film and is attached to one side of the polarizing layer.

17. The light emitting display device of claim 16, wherein
the absorption axis of the polarizing layer has an angle of about 45 degrees with respect to the first direction.

18. The light emitting display device of claim 12, further comprising
an adhesive layer disposed between the positive A plate and the negative A plate.

19. The light emitting display device of claim 12, further comprising,
an adhesive layer disposed between the negative A plate and the polarizer.

20. The light emitting display device of claim 12, wherein
the positive C plate, the positive A plate, the negative A plate, and the negative C plate each have positive wavelength dispersion characteristics, and wherein the light emitting display device has negative wavelength dispersion characteristics at a light emitting display device front.
